(19) United States
(12) Patent Application Publication
(10) Pub. No.: US 2006/0171305 A1
(43) Pub. Date: Aug. 3, 2006

(54) Access point channel forecasting for seamless station association transition

(75) Inventors: Lawrence V. Stefani, Reading, MA (US); Michael Yuen, Waltham, MA (US)

Correspondence Address: McGUINNESS & MANARAS LLP, 125 NAGOG PARK, ACTON, MA, 01720, US

(73) Assignee: Autocell Laboratories, Inc.

(21) Appl. No.: 11/103,401

(22) Filed: Apr. 11, 2005

Related U.S. Application Data
(60) Provisional application No. 60/649,799, filed on Feb. 3, 2005.

(51) Int. Cl. G01R 31/08

(52) U.S. Cl. 370/228

(57) ABSTRACT

Seamless migration of an AP/STA link across channels to compensate for a changing RF environment is achieved by forecasting alternate AP communication channels to an STA prior to loss of connectivity on the link. The AP, when identifying a preferred communication channel, also identifies an alternate communication channel, and communicates this alternate channel to a coupled STA. In the event that communication between the AP and the STA is lost, the STA can quickly predict the new location of the AP, and migrate to the new channel without loss of communication state. The AP is not required to communicate to any STA that it has switched stations. Rather, the fact that the AP has switched is inferred at the STA by the inability of the STA to communicate with the AP. Thus the present invention may be used to preserve link state when a communication channel used by the AP/STA link is blocked.

### CROSS-REFERENCE TO RELATED APPLICATIONS

A claim of priority is made under 35 U.S.C. 1.119(e) to U.S. Provisional Patent Application Ser. No. 60/649,799 entitled Interference Counter Measures for Wireless LANs, filed Feb. 3, 2005, which is incorporated herein by reference.

This application may be related to patent application Ser. No. ______. Attorney docket number 160-091, entitled “Backup Channel Selection in Wireless LANS”, by Backes et al., filed on even date herewith, which is incorporated herein by reference.

### FIELD OF THE INVENTION

This invention is generally related to wireless communications, and more particularly to a method and apparatus for seamlessly transitioning an access point and station association when changing transmission channels.

### BACKGROUND OF THE INVENTION

As it is known in the art, a Wireless Local Area Network (WLAN) is a local-area network that uses high-frequency radio waves, rather than wires, to communicate between nodes. Various types of wireless LAN networks exist, and an example of a wireless data network is described in “IEEE Standard for Information technology—Telecommunications and information exchange between systems—Local and metropolitan area networks—Specific requirements—Part 11: Wireless LAN Medium Access Control (MAC) and Physical Layer (PHY) specifications, incorporated herein by reference (hereinafter “802.11”).

Each wireless network typically includes an Access Point device (AP) to allow one or more stations (STAs) to connect to a wired LAN. Software, executing at a station, selects the best AP available for connection to the LAN, taking into consideration various characteristics of signals received from neighboring APs.

Wireless local area network (“WLAN”) products, such as products based on the IEEE 802.11 standard, operate in a defined frequency spectrum, with the APs free to use any available frequency in the spectrum. During initialization, an AP selects one of the transmission frequencies in the spectrum for communication. The transmission frequency is commonly referred to as a channel. Many methods may be used by an AP to select a channel, but in general, the channel selected by the AP is the channel having the lowest amount of radio interference. Once the AP has selected a channel, it signals its' availability to neighboring stations. When a station wishes to join a WLAN, it scans the frequency spectrum in search of Beacons to discover available APs, and selects one of the discovered APs for association. It then begins the process of building a connection.

The connection building process is time consuming, involving steps of authentication and association of the STA, the creation of forwarding table, the distribution of routing information, etc. Thus it is desirable to maintain STA and AP associations for as long as possible to compensate for time used establishing the connection. However, a problem arises when changes in the radio environment increase the amount of interference on the transmission channel to a level that compromises station/AP communication. When the interference on a transmitting channel reaches an undesirable threshold, the AP must change transmission channels. As a result, station connections are lost and any pending packets are dropped. Each dropped station must then re-initiate the discovery and association process, causing significant delay in communications with the station and undesirably affecting the overall WLAN performance.

One attempt at maintaining the AP and STA connection in the particular instance when the AP is operating in a dedicated frequency spectrum has been suggested in 802.11 (h). IEEE 802.11 reserves certain frequencies in the available communication spectrum for certain high priority devices. High priority devices may include military radars or medical devices. General purpose APs are permitted to use the frequencies allocated to the high priority devices in the absence of a higher priority device, but the AP is required to minimize its interference on the channel should a higher priority device start to use the channel. IEEE standard, section 802.11h addresses the problem of transitioning communications by an AP on a channel when an interfering, higher priority device is introduced on the channel. One scheme suggested in 802.11 (h) is Dynamic Frequency Selection (DFS); DFS detects the presence of other devices on a channel and automatically switches the network to another channel if and when such signals are detected. The method suggested by DFS to switch channels involves an AP issuing Beacons and a count down value indicating the remaining number of times that the AP will Beacon on the channel before moving to an alternate channel. The AP and STAs count down the beacons, and synchronously transition to an alternate channel for transmissions.

One problem with DFS is that it requires the AP to be able to communicate its intent to switch channels to the STA; The DFS method is ineffective in radio frequency environments when channel interference has increased to levels that disable AP and STA communication.

### SUMMARY OF THE INVENTION

According to one aspect of the invention, a method for maintaining an association with a station by an access point in a wireless network comprising the steps of selecting a first channel and at least one alternate channel for transmissions by the access point, storing, in a channel forecast table, the at least one alternate channel, forwarding the channel forecast table to the station, detecting a loss of availability of the first channel, and forwarding communications on the alternate channel without notice to other devices in the network.

According to another aspect of the invention, a network device for use as an access point in a wireless network includes channel selection means for selecting a first channel and at least one alternate channel for transmissions by the access point, a channel forecast table for storing the at least one alternate channel, and forwarding means for forwarding the channel forecast table to a wirelessly coupled station.

According to a further aspect of the invention, a method of maintaining an association with an access point by a station in a wireless network includes the steps of receiving, from the access point, a channel forecast table including at least one alternate transmission channel, communicating with the access point on a first channel, and upon a detection of a loss of transmissions by the access point on the first channel, switching to the at least one alternate transmission channel.

According to another aspect of the invention, a network device includes means for establishing communications with an access point in a wireless network on a first channel, a channel forecast table, storing at least one alternate channel for communications with the access point, means for detecting a loss of connectivity with the access point; and means for switching to the alternate channel to locate the access point.

With such arrangements, an AP can broadcast potential alternate communication channels to an STA. In the event that interference on the communication link between the STA and the AP degrade to a point that connectivity is lost, the STA can quickly predict the location of the AP, and resume communication on the link, albeit at an updated frequency, without loss of state. Thus the present invention provides a mechanism for seamlessly transitioning an AP/STA link across channels to compensate for changing RF environments.

### BRIEF DESCRIPTION OF THE FIGURES

FIG. 1 is a block diagram of a WLAN in which the present invention may be used;

FIG. 2 is a block diagram illustrating several components that may be included in an access point of the present invention;

FIG. 3 is a flow diagram provided to illustrate several exemplary steps that may be performed by an access point of FIG. 2;

FIG. 4 is a block diagram illustrating several components that may be included in a wireless station device of the present invention; and

FIG. 5 is a flow diagram provided to illustrate several exemplary steps that may be performed by a station of FIG. 4.

### DETAILED DESCRIPTION

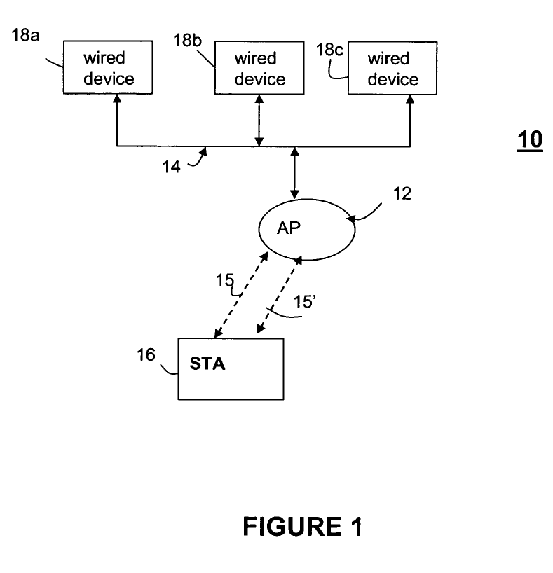

Referring to FIG. 1 a wireless access point (AP) 12 is operative to provide network access to a wireless end stations (STAs) 16 such as a personal computer, PDA, notebook computer, phone or other wireless device. A STA is typically a mobile device coupled via a radio frequency connection 15 to the AP 12. The AP is typically a stationary device having a wire-line connection with another network device such as devices 18a-18c, which may be, for example, a personal computer, switch, router or server in a network. Communications between the AP and the STAs are typically two-way at a selected radio frequencies, or channels.

In one embodiment of the invention, the AP 12 is adapted to recognize and respond to interference in a manner described in patent application attorney docket number 160-091, entitled “Backup Channel Selection in Wireless LANS”, incorporated by reference above. An AP as described therein includes a table of interference profiles stored in memory which are indicative of particular sources of interference. An interference profile is generated for each potential alternate transmission channel available to the AP. Using the interference profile information, the AP identifies the most desirable channel for transmission. According to one aspect of the present invention, the AP then generates a ranked list of a preselected number of alternate transmission channels, with the top ranked alternate transmission channel being the next most desirable transmission frequency. The determination as to desirability of the channel may be based on criteria such as that described in ‘Backup Channel Selection’, or alternatively may be based on the satisfaction of any other criteria, including but not limited to load balancing, power usage, service requirements, etc., and thus the present application is not limited to any particular method of selecting the alternate channels.

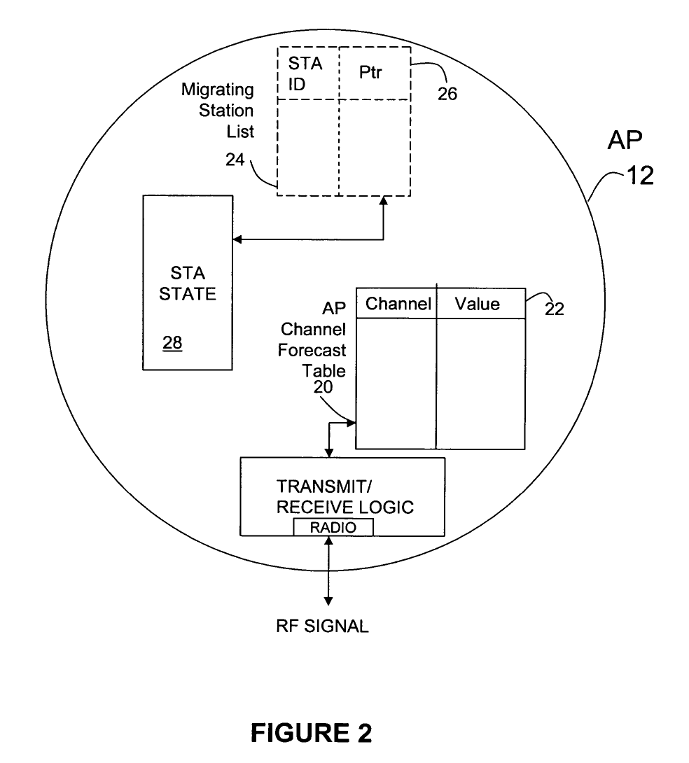

FIG. 2 illustrates several components which may be included in an AP supporting this invention, including a channel forecast table 20. The channel forecast table 20 includes a predetermined number of forecast entries 22, each entry including at least a channel identifier indicating a communication frequency for the channel. The channel identifier indicates an alternate transmission channel which may be used by the AP should the transmission channel currently used by the AP become undesirable. The transmission channel may become undesirable for any variety of reasons, including an increase of interference on the channel, a receipt of a request at the AP to stop using the channel, or other reason. The forecast entry 22 also may include any other number of useful fields; for example a value field associated with the desired criteria may be included to facilitate sorting of the table. Other fields which may be advantageous to the communication of a desired alternate channel may also be included herein, and thus the present invention is not limited to the inclusion of any particular entries other than the channel identifier in the table.

As mentioned above, the channel forecast table may be forwarded to the station upon initial association between the station and the AP. Advantageously, in APs having the capability of performing background scanning of available frequencies to monitor changing characteristics of the channels, the channel forecast table is also periodically updated to reflect the changing radio frequency environment. Updated versions of the table may then periodically be forwarded to the station.

The AP is also shown to include STA State storage 28 and a Migrating Station list 24. STA State herein represents information used by the AP to communicate with each of the stations. The STA State includes both state that is obtained at initialization by association of the STA with the AP, and any other data that may be gathered at the AP thereafter. Thus the STA State may include a STA identifier, authentication information for the STA, queued data frames, association IDs, encryption state, etc., and the present invention is not limited to the storage of any particular state.

When an STA disassociates from an AP, the STA State of the disassociated STA is typically deleted to free resources at the AP. Because of the time used to build the STA State, however, it is desirable to maintain AP and STA associations for as long as possible. The present invention, by forecasting potential channels to the STA prior to the loss of communications between the STA and AP pair, enables the STA to predict the location of the AP, thereby maintaining the association and preserving the STA state.

However, there may be instances wherein an AP determines that the state of a particular STA need not be preserved when the AP migrates to a different channel. If the AP can identify the STAs that are not going to migrate, the STA State associated with non-migrating STAs can be deleted, thereby freeing resources for other AP connections. According to one embodiment of the invention, a Migrating Stations List 24 may advantageously be maintained at the AP (although it is not required and is thus shown in dashed lines). The Migrating Stations list identifies STA state that is to be preserved when the AP switches channel. The list of migrating stations includes those stations that have indicated to the AP that they will attempt to re-associate with the AP in the event that the AP should cease transmissions on the channel of current association. The indication may be an active indication of the desire to participate (or fail to continue to participate), through the issuance of a response to the receipt of the Channel Forecast. Alternatively, the AP may infer that the STA is a participating STA by analysis of a version of software or hardware executing on the STA (as legacy STAs may not include the support). Other methods of determining that the STA is participating may also be used, and the present invention is not limited to any manner of populating the Migrating Stations list. In addition, although the below embodiment refers to a specific list, it is also envisioned that the information about whether a STA is participating in channel migration may be stored in a variety of manners, such as a state bit associated with the STA state, etc., and the present invention is also not limited to a specific list of stations.

The embodiment of the Migrating Stations List 24 of FIG. 2 is shown to include a number of entries 26, each entry associated with a different station and including a unique station identifier. Entry 26 is also shown to include a pointer to STA State associated with the STA identifier. Other data may also be included and the present invention is not limited to the provision of any particular data other than an identifier of participating stations.

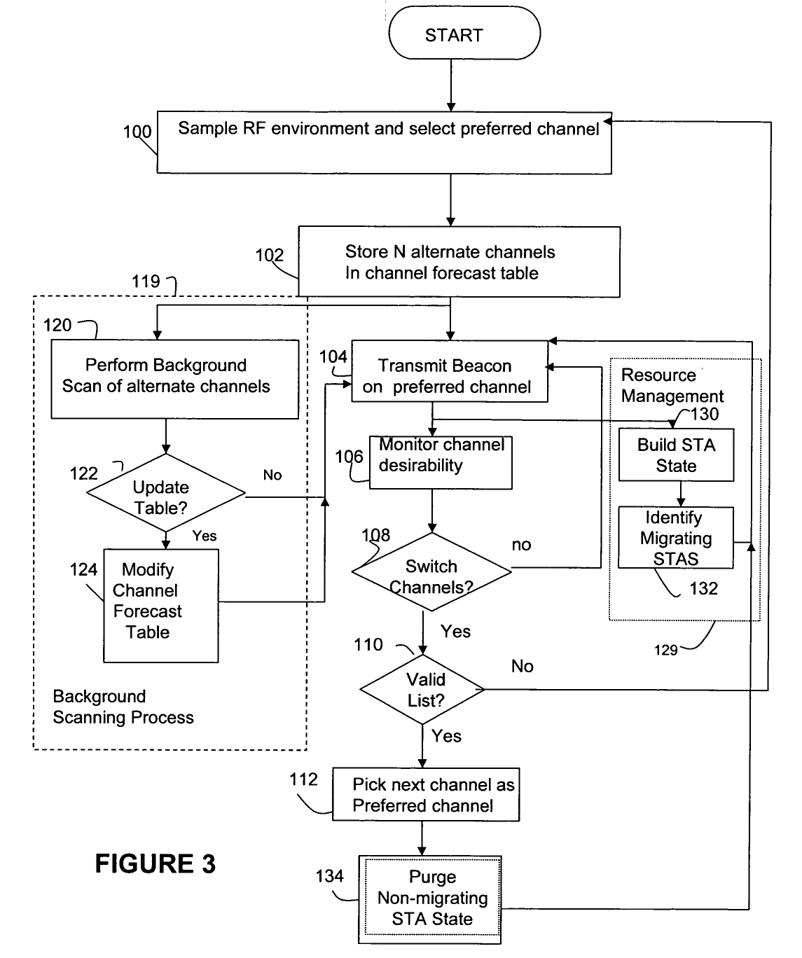

Referring now to FIG. 3, a flow diagram is provided to illustrate several exemplary steps that may be performed at an AP of various embodiments of the invention. At step 100 the AP samples the RF environment and selects a preferred channel for transmission by executing any variety of channel selection processes. A list of N alternate transmission channels is stored in channel forecast table 20 at step 102, and at step 104 the AP indicates its presence on the channel by transmitting messages on the channel announcing its presence. The announcement messages are known in 802.11 as ‘Beacon’ messages, and include a variety of information about the AP. In one embodiment of the invention, the Beacon includes a copy of the channel forecast table, although it is also envisioned that the channel forecast table may be sent to the STA in a separate message during or after connection establishment.

As described in 802.11, the Beacons are generally transmitted to the STAs at 100 ms intervals to indicate presence. The AP may be performing several tasks in between the issuance of Beacons. One of the processes advantageously performed by an AP of the present invention is the process of Background Scanning Process 119, shown in FIG. 3 in dashed lines to indicate that it is not essential to the invention but is advantageously included in one embodiment. During Background Scanning the AP continually monitors transmission frequencies to locate desirable alternate transmission frequencies. Thus at step 120 the AP performs the background scanning process, periodically looking for changing characteristics of the channels at step 122 and modifying the channel forecast table at step 124. In a system wherein the channel forecast table is forwarded in a Beacon, then the step of transmitting the Beacon at step 104 causes the modified channel forecast table to be forwarded to the STA.

Another process that may be performed by the AP is a Resource Management Process 129, shown in FIG. 3 outlined by a dotted line to indicate that it is not essential to the invention but may be included in an exemplary embodiment. As described above, as the AP associates with an STA, it builds STA State, which is stored in a resource at the AP. The AP determines, at step 132, whether the STA is an STA which will attempt migration to alternate channels with the AP, and stores this information in some form (for example Migrating Station List 24) at the AP.

In addition to the Background Scanning process and the Resource Management Process, and the step of issuing Beacons, the AP additionally monitors the existing transmit channel at step 106 to identify when the channel becomes undesirable. The channel may become undesirable either due to interference on the channel, because of a detection of a higher priority device seeking to use the channel or any other reason. If at step 108 it is determined that it is not desirable to change channels, the AP continues to transmit Beacons on the preferred channel at step 104.

However, if at step 108 it is determined that the channel should be switched then at step 110 it is evaluated whether the channel list is still valid. The channel list is valid if there are remaining alternative channels on the list that have not been determined to be undesirable, and thus step 110 identifies some threshold determination with regard to the list has been met. For example, the AP may cycle through the list of channels a predetermined number of times until it is determined that none of the channels previously thought to be desirable are available for transmission. If the list is no longer valid, the process returns to step 100, where the AP re-initiates channel selection.

If it is determined at step 110 that the list is valid, then at step 112 the AP selects the next channel in the channel forecast list as the preferred transmission channel. In an embodiment that performs resource management, at step 134 the AP purges the state of non-migrating STAs from STA State resource 28, and the process returns to step 104, whereby Beacons are transmitted on the new, preferred channel.

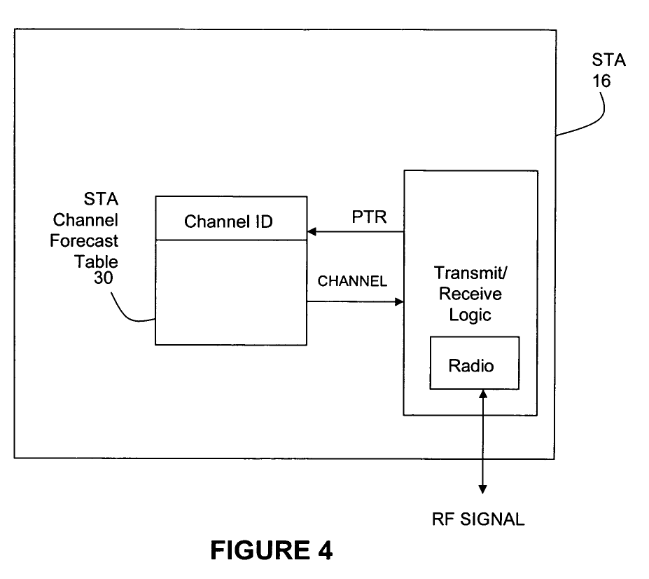

Referring now to FIG. 4, a block diagram is shown of logic that may be added to a typical STA to support the present invention. The STA 16 is shown to include STA channel forecast table 30 for storing a number of alternate transmission frequencies received from the AP. The number of alternate channels included in the alternate channel list is a matter of design choice, and need not be constant; rather it is envisioned that the number and values of the transmission frequencies may vary in accordance with changes in the RF environment of the AP.

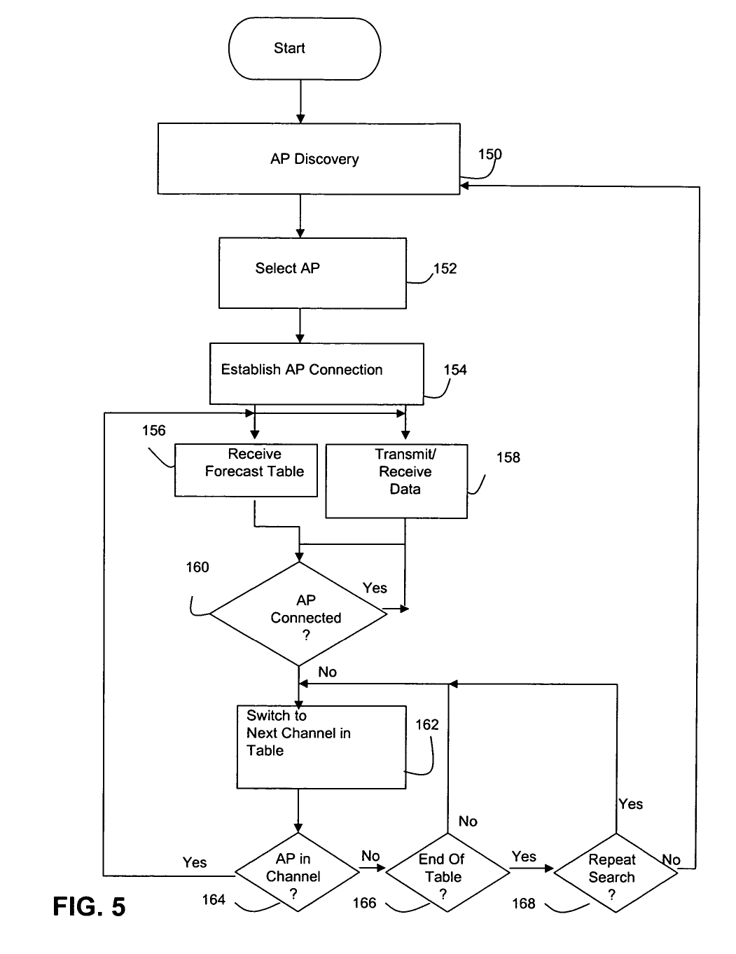

FIG. 5 illustrates several steps that may be performed at an STA supporting the present invention and including the channel forecast table 30 of FIG. 4. At step 150 the STA initiates the process of AP Discovery. One method that may be used to discover APs is described in U.S. patent application “Transmission Channel Selection Apparatus” Ser. No. 10/781,22, filed Feb. 18, 2004 (incorporated herein by reference and hereinafter referred to as the Channel Selection patent). In general the STA scans the frequency spectrum for Beacons, indicating AP presence. At step 152 the STA selects one of the discovered APs for communication and at step 154 initiates the process of connecting with the AP, and at step 158 the AP and STA begin exchange of data packets. According to the present invention, as part of the connection process or shortly thereafter, at step 156 the STA receives a channel forecast table 30 (FIG. 4). The STA may, at this time, indicate a Migration Intent to the AP. As mentioned previously, the migration intent may be either explicit, via a command, or may alternatively be inferred by the AP from certain information forwarded by the STA.

The process then continues at step 160, where the STA monitors the connection with the AP to identify when a connection is lost. One method which may be used by an STA to identify a loss in a connection is by monitoring the receipt of Beacons from the AP. As mentioned previously, each AP generally beacons at 100 ms intervals. An alternative method which may be used to monitor connectivity is to have the AP send a ‘keep-alive’ message to the STA. In one embodiment the ‘keep-alive’ frequency may be either a Beacon sent at a higher frequency, or alternatively an independent communication sent at a higher frequency than the Beacons. In any case, the ‘keep-alive’ is sent at a higher frequency so that the STA may more quickly detect the loss of connection with the AP, as the current Beacon frequency does not permit a STA to detect AP loss in a time necessary to continue voice communications without degradation. In an instance when an independent signal other than a Beacon is used to signal connectivity, the ‘keep-alive’ may forward only a small amount of data to indicate the presence of the connection, and thus does not use as much bandwidth per communication as a Beacon. Minimizing the size of the communication is desirable because it helps to overcome any bandwidth issues caused by increasing the frequency of the ‘keep-alive’ communication.

Whichever method is used to indicate connectivity, if it is determined that there has been a loss in connectivity with the AP, at step 162 the STA switches its radio to the next channel in the forecast table. At step 164 it determines whether there is an AP in the next channel of the forecast table. If so, then the process returns to steps 156, 158, and data exchange between the AP and STA seamlessly transitions to the new channel, without loss of data. If at step 164 the AP is not located in the channel, then the STA cycles through the forecast table, repeating steps 162 and 164 until it is determined at step 166 that the end of the table has been reached. At step 168, after the end of the table is reached, it is determined whether the STA wishes to repeat the scan of available AP frequencies. For example the STA could cycle through the list of alternate channels in search of the AP for a predetermined number of times before determining that it has lost the AP. If it does determine that it has lost the AP, then the process returns to step 150, and the AP discovery process begins anew. It should be noted that the time used to determine whether the AP can be found on another channel is minimal in comparison to the time needed to re-initiate a connection with an AP.

Accordingly, an improved method and apparatus of preserving AP/STA state in a WLAN has been shown and described. Seamless migration of an AP/STA link across channels to compensate for a changing RF environment is achieved by forecasting alternate AP communication channels to an STA prior to loss of connectivity on the link. The AP, when identifying a preferred communication channel, also identifies an alternate communication channel, and communicates this alternate channel to a coupled STA. In the event that communication between the AP and the STA is lost, the STA can quickly predict the new location of the AP, and migrate to the new channel without loss of communication state. The AP is not required to communicate to any STA that it has switched channels. Rather, the fact that the AP has switched is inferred at the STA by the inability of the STA to communicate with the AP. Thus the present invention may be used to preserve link state when a communication channel used by the AP/STA link is blocked.

Having described exemplary embodiments, it will be appreciated that various modifications may be made without diverging from the spirit and scope of the invention. For example, several figures are flowchart illustrations of methods, apparatus (systems) and computer program products according to an embodiment of the invention. It will be understood that each block of the flowchart illustrations, and combinations of blocks in the flowchart illustrations, can be implemented by computer program instructions. These computer program instructions may be loaded onto a computer or other programmable data processing apparatus to produce a machine, such that the instructions which execute on the computer or other programmable data processing apparatus create means for implementing the functions specified in the flowchart block or blocks. These computer program instructions may also be stored in a computer-readable memory that can direct a computer or other programmable data processing apparatus to function in a particular manner, such that the instructions stored in the computer-readable memory produce an article of manufacture including instruction means which implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions specified in the flowchart block or blocks.

Those skilled in the art should readily appreciate that programs defining the functions of the present invention can be delivered to a computer in many forms; including, but not limited to: (a) information permanently stored on non-writable storage media (e.g. read only memory devices within a computer such as ROM or CD-ROM disks readable by a computer I/O attachment); (b) information alterably stored on writable storage media (e.g. floppy disks and hard drives); or (c) information conveyed to a computer through communication media for example using base band signaling or broadband signaling techniques, including carrier wave signaling techniques, such as over computer or telephone networks via a modem.

While the invention is described through the above exemplary embodiments, it will be understood by those of ordinary skill in the art that modification to and variation of the illustrated embodiments may be made without departing from the inventive concepts herein disclosed. Moreover, while the preferred embodiments are described in connection with various illustrative program command structures, one skilled in the art will recognize that the system may be embodied using a variety of specific command structures. Accordingly, the invention should not be viewed as limited except by the scope and spirit of the appended claims.

1. A method for maintaining an association with a station by an access point in a wireless network comprising the steps of:
selecting a first channel and at least one alternate channel for transmissions by the access point;
storing, in a channel forecast table, the at least one alternate channel;
forwarding the channel forecast table to the station;
detecting a loss of availability of the first channel; and
initiating communications on the alternate channel without notice to other devices in the network.

2. The method according to claim 1, further comprising the step of:
transmitting a first portion of a data sequence to the station on the first channel; and
transmitting a second portion of the data sequence to the station on the alternate channel.

3. The method according to claim 1, wherein the step of forwarding the channel forecast table is performed at initialization of the access point.

4. The method according to claim 1, further comprising the steps of:
scanning channels to identify desirable transmission channels;
updating the channel forecast table to include the desirable transmission channels; and
transmitting the updated channel forecast table to the station.

5. The method according to claim 1 further including the steps of:
receiving an indication from the station regarding an ability of the station to utilize the channel forecast table; and
selectively storing state for the station in response to the received indication.

6. A network device for use as an access point in a wireless network comprising:
channel selection means for selecting a first channel and at least one alternate channel for transmissions;
a channel forecast table for storing the at least one alternate channel; and
forwarding means for forwarding the channel forecast table associated stations.

7. The network device of claim 6 further comprising:
a channel migration group table for storing identifiers of stations in the wireless network capable of seamlessly transitioning with the access point from the first channel to the at least one alternate channel.

8. A method of maintaining an association with an access point by a station in a wireless network including the steps of:
receiving, from the access point, a channel forecast table including at least one alternate transmission channel;
communicating with the access point on a first channel; and
upon a detection of a loss of transmissions by the access point on the first channel, switching to the at least one alternate transmission channel.

9. The method of claim 8 wherein the channel forecast table is received at initial association with the access point.

10. The method of claim 8 further comprising the steps of periodically receiving updates to the channel forecast table and updating the channel forecast table responsive to the updates.

11. The method of claim 8 including the step of indicating to the access point that the station is capable of seamlessly transitioning to the alternate channel with the access point.

12. The method according to claim 8 including the steps of:
determining whether the access point is at the first one of the at least one alternate channels in the channel forecast table; and
responsive to a determination that the access point is not at the first one of the at least one alternate channels in the channel forecast table, cycling through the channel forecast table a predetermined number of times to locate the access point.

13. The method according to claim 12, further including the step of attempting to locate an alternative access point responsive to failure to locate the access point at any of the first channel or alternate channels in the channel forecast table.

14. A network device including:
means for establishing communications with an access point in a wireless network on a first channel;
a channel forecast table, storing at least one alternate channel for communications with the access point;
means for detecting a loss of connectivity with the access point; and
means for switching to the alternate channel to locate the access point.
